(19) United States
(12) Patent Application Publication
(10) Pub. No.: US 2015/0160269 A1
(43) Pub. Date: Jun. 11, 2015

(54) CIRCUIT STRUCTURE FOR MEASURING INPUT VOLTAGE

(71) Applicant: ASIAN POWER DEVICES INC., Taoyuan County (TW)

(72) Inventors: Yu-Chi LAI, Taoyuan County (TW); Tsung-Liang HUNG, Taoyuan County (TW); Ya-Lun OUYANG, Taoyuan County (TW)

(21) Appl. No.: 14/461,899

(22) Filed: Aug. 18, 2014

(30) Foreign Application Priority Data
Dec. 5, 2013 (TW) 102223042

(51) Int. Cl. G01R 19/00; G01R 15/04

(52) U.S. Cl. CPC G01R 19/0084; G01R 15/04

(57) ABSTRACT

A circuit structure for measuring an input voltage includes an inductance element, an extra wire winding and a processing element. The extra wire winding additionally wraps around the inductance element. The processing element is coupled to the extra wire winding. The inductance element receives the input voltage and works. The extra wire winding induces the input voltage to obtain an induction signal. The extra wire winding sends the induction signal to the processing element. The processing element is configured to calculate a voltage value of the input voltage according to the induction signal.

### BACKGROUND OF THE INVENTION

1. Field of the Invention

The present invention relates to a circuit structure for measuring an input voltage, and especially relates to a circuit structure that measures the input voltage by an extra wire winding.

2. Description of the Related Art

Technologies and economy are progressing and developing every day. People have to use more and more electronic devices. Recently, most of the electronic devices are slim and light because the power electronic technology is improved greatly. The power converter of the electronic device is demanded to be compact and lightweight as well.

Moreover, there are various electronic devices nowadays. Different electronic device may require different power supply. The electronic device may not be operated if the power supply is not suitable (the voltage supplied by the power supply is too low). The electronic device may be damaged if the power supply is not suitable (the voltage supplied by the power supply is too high). Moreover, even if the power supply is suitable for the electronic device, the results mentioned above may happen if the voltage supplied by the wall socket is not suitable. Therefore, a related apparatus for detecting the input voltage is provided and arranged in the electronic device or the power supply. Most of the market-available apparatus for detecting the input voltage comprises a transformer for inducing the input voltage. Therefore, the area of the printed circuit board of the electronic device or the power supply is increased. The cost is also increased due to the additional transformer and printed circuit board size. Thus, the electronic device or the power supply will not be compact and lightweight.

### SUMMARY OF THE INVENTION

In order to solve the above-mentioned problems, the objective of the present invention is to provide a circuit structure for measuring input voltage. An inductance element of the circuit structure is additionally wrapped by an extra wire winding which is different from the local wire winding of the inductance element. The inductance element receives the input voltage and then the extra wire winding induces the input voltage to obtain an induction signal. The extra wire winding sends the induction signal to a processing element of the circuit structure. The processing element is configured to calculate a voltage value of the input voltage according to the induction signal.

In order to achieve the objective of the present invention mentioned above, the circuit structure comprises the inductance element, the extra wire winding and the processing element. The extra wire winding additionally wraps around the inductance element. The processing element is coupled to the extra wire winding. The inductance element receives the input voltage and works. The extra wire winding induces the input voltage to obtain the induction signal. The extra wire winding sends the induction signal to the processing element. The processing element is configured to calculate the voltage value of the input voltage according to the induction signal.

The circuit structure measures the input voltage by only additionally wrapping around the inductance element with the extra wire winding, and then the induction signal induced by the extra wire winding is calculated by the processing element to obtain the voltage value of the input voltage. Therefore, the size of the printed circuit board using the proposed structure can be reduced.

### BRIEF DESCRIPTION OF DRAWING

FIG. 1 shows a block diagram of the circuit structure of the present invention.

FIG. 2 shows that the extra wire winding wraps around the inductance element.

### DETAILED DESCRIPTION OF THE INVENTION

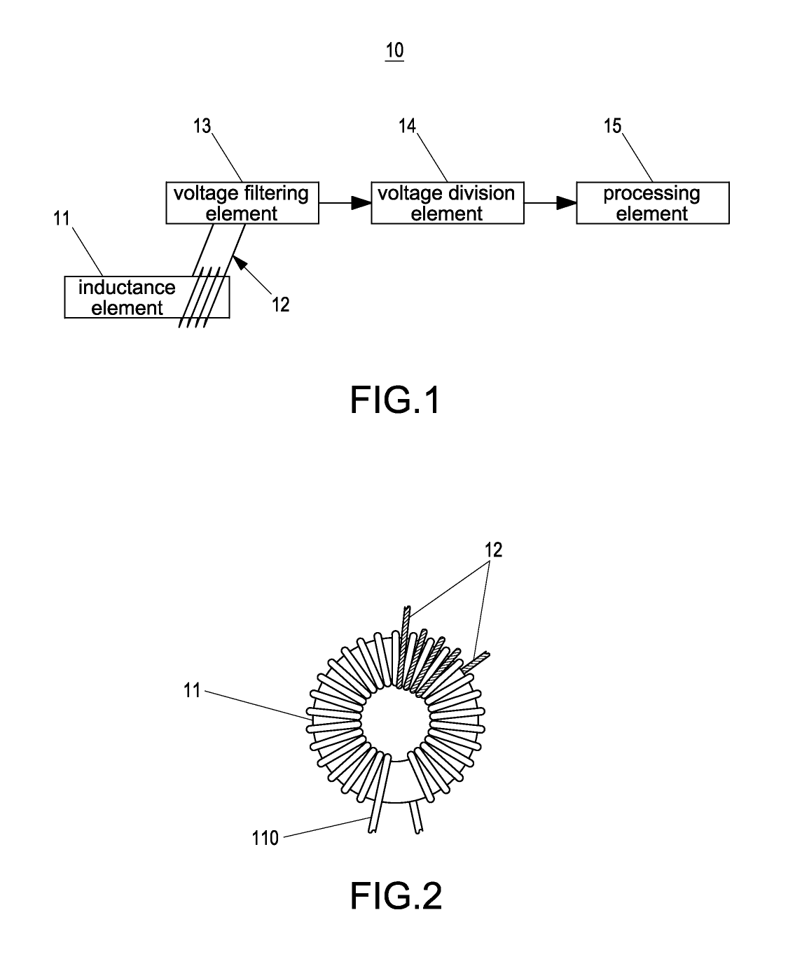

FIG. 1 shows a block diagram of the circuit structure of the present invention. FIG. 2 shows that the extra wire winding that wraps around the inductance element. A circuit structure 10 comprises an inductance element 11, an extra wire winding 12, a voltage filtering element 13, a voltage division element 14 and a processing element 15. The extra wire winding 12 wraps around the inductance element 11. The voltage filtering element 13 is coupled (electrically connected) to the extra wire winding 12. The voltage division element 14 is coupled (electrically connected) to the voltage filtering element 13 and the processing element 15. The voltage filtering element 13 can be a diode or any other equivalent elements. The voltage division element 14 can be a voltage division resistor or any other equivalent elements. The processing element 15 can be a processor, a microprocessor or any other equivalent elements. The inductance element 11 comprises a local wire winding 110. The extra wire winding 12 is different from the local wire winding 110 of the inductance element 11.

The inductance element 11 induces the input voltage to the circuit structure 10 when the electronic device or power supply is under operation. The circuit structure 10 can boost or reduce the input voltage. The extra wire winding 12 wrapping around the inductance element 11 induces the input voltage to obtain an induction signal according to the principle of induction electromotive force. The induction signal can be an induced current (voltage). The extra wire winding 12 sends the induction signal to the processing element 15. The processing element 15 is configured to calculate a voltage value of the input voltage according to the induction signal. Moreover, in order to avoid damaging the processing element 15, the voltage filtering element 13 and the voltage division element 14 are coupled between the extra wire winding 12 and the processing element 15. The voltage filtering element 13 coupled to the extra wire winding 12 can avoid a negative voltage passing through. The voltage division element 14 arranged between the voltage filtering element 13 and the processing element 15 can avoid an excessive high voltage entering the processing element 15.

The present invention can measure the input voltage, so that the user can easily know whether the input voltage is in the voltage standard of the system or not. The volume of the circuit structure 10 is small, so that the volume of the system can be reduced for better industry competition.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A circuit structure for measuring an input voltage, the circuit structure comprising:
an inductance element;
an extra wire winding wrapping around the inductance element; and
a processing element coupled to the extra wire winding,
wherein the inductance element receives the input voltage and works; the extra wire winding induces the input voltage to obtain an induction signal; the extra wire winding sends the induction signal to the processing element; the processing element is configured to calculate a voltage value of the input voltage according to the induction signal.

2. The circuit structure in claim 1, wherein the processing element is a processor or a microprocessor.

3. The circuit structure in claim 2, further comprising:
a voltage filtering element coupled to the extra wire winding; and
a voltage division element coupled to the voltage filtering element and the processing element.

4. The circuit structure in claim 3, wherein the voltage filtering element is a diode.

5. The circuit structure in claim 4, wherein the voltage division element is a voltage division resistor.
